(19) United States
(12) Patent Application Publication
(10) Pub. No.: US 2024/0400897 A1
(43) Pub. Date: Dec. 5, 2024

(54) FLUORESCENT POWDER AND LIGHT-EMITTING DEVICE

(71) Applicant: DENKA COMPANY LIMITED, Chuo-ku, Tokyo (JP)

(72) Inventor: Shunsuke MITANI, Tokyo (JP)

(73) Assignee: DENKA COMPANY LIMITED, Chuo-ku, Tokyo (JP)

(21) Appl. No.: 18/688,846

(22) PCT Filed: Jun. 29, 2022
(86) PCT No.: PCT/JP2022/026102

§ 371 Date: Mar. 4, 2024

(30) Foreign Application Priority Data
Sep. 8, 2021 (JP) 2021-146394

(51) Int. Cl. C09K 11/77; H01L 33/50

(52) U.S. Cl. CPC C09K 11/7728; H01L 33/502

(57) ABSTRACT

According to an aspect of the present disclosure, there is provided a fluorescent substance powder containing a plurality of CASN-based fluorescent substance particles. Average circularity of fluorescent substance particles having a particle size of 1 μm or greater among the CASN-based fluorescent substance particles is 0.820 or greater, and a standard deviation of the circularity is less than 0.080.

### TECHNICAL FIELD

The present disclosure relates to a fluorescent substance powder and a light-emitting device.

### BACKGROUND ART

A light-emitting device including a light-emitting element such as a light-emitting diode is used in general lighting, a backlight for a liquid crystal display, an LED display, and the like. In the LED display, for example, a light-emitting element including a light-emitting element that emits blue light and a wavelength converter that absorbs primary light from the light-emitting element and emits light of a different wavelength is used. In addition, as the wavelength converter, various fluorescent substances such as a red-fluorescent substance and a green-fluorescent substance are used.

As the red-fluorescent substance, CASN-based fluorescent substances such as a CASN fluorescent substance and SCASN fluorescent substance are known (For example, Patent Literature 1 and the like). Generally, the CASN-based fluorescent substances are synthesized by heating a raw material powder containing europium oxide or europium nitride, calcium nitride, silicon nitride, and aluminum nitride.

### CITATION LIST

### Patent Literature

Patent Literature 1: International Publication WO 2005/052087 A1

### SUMMARY OF INVENTION

### Technical Problem

From the viewpoint of obtaining an LED display with high color reproducibility, it is important to use a fluorescent substance that exhibits a sufficient light-emitting intensity as a green-fluorescent substance and a red-fluorescent substance, and as in a micro LED display, in a case where a cured resin layer filled with the green-fluorescent substance or the red-fluorescent substance is disposed on an LED of blue light, ultraviolet light, or the like, and multi-coloring is desired by wavelength conversion in which primary light such as blue light and ultraviolet light is set as exciting light, it is required to increase a color gamut of the cured resin layer.

An object of the present disclosure is to provide a fluorescent substance powder containing a red-fluorescent substance which is capable of exhibiting large chromaticity X of a cured resin layer when being dispersed in a resin to form the cured resin layer. Another object of the present disclosure is to provide a light-emitting device that includes the fluorescent substance powder and is capable of exhibiting excellent color reproducibility.

### Solution to Problem

The present disclosure provides the following [1] to [6].
[1] A fluorescent substance powder containing:
a plurality of CASN-based fluorescent substance particles,
wherein average circularity of fluorescent substance particles having a particle size of 1 μm or greater among the CASN-based fluorescent substance particles is 0.820 or greater, and a standard deviation of the circularity is less than 0.080.
[2] The fluorescent substance powder according to [1],
wherein an average aspect ratio of fluorescent substance particles having a particle size of 1 μm or greater among the CASN-based fluorescent substance particles is 1.275 or less.
[3] The fluorescent substance powder according to [1] or [2],
wherein a main crystal phase constituting the CASN-based fluorescent substance has the same structure as in a CaAlSiN₃ crystal phase.
[4] The fluorescent substance powder according to any one of [1] to [3],
wherein the fluorescent substance powder is expressed by a general formula of (CaₓSr_{y}Eu_{z})AlSiN₃, and in the general formula, conditions of 0≤x<1, 0<y<1, and 0<z<1 are satisfied.
[5] The fluorescent substance powder according to any one of [1] to [4],
wherein a wavelength of a light-emission peak is 605 nm to 670 nm.
[6] A light-emitting device, including:
a light-emitting element that emits primary light; and
a wavelength converter that absorbs a part of the primary light and emits secondary light having a wavelength longer than a wavelength of the primary light,
wherein the wavelength converter contains the fluorescent substance powder according to any one of [1] to [5].

According to an aspect of the present disclosure, there is provided a fluorescent substance powder containing: a plurality of CASN-based fluorescent substance particles. Average circularity of fluorescent substance particles having a particle size of 1 μm or greater among the CASN-based fluorescent substance particles is 0.820 or greater, and a standard deviation of the circularity is less than 0.080.

The fluorescent substance powder contains the CASN-based fluorescent substance useful as a red-fluorescent substance, the average circularity of particles having a particle size of 1 μm or greater among the CASN-based fluorescent substance particles is relatively higher, and a deviation of the circularity is suppressed. According to this, in a case where the fluorescent substance powder is dispersed in a resin to form a cured resin layer, the cured resin layer can exhibit great chromaticity. The reason why the effect is obtained is not clear, but present inventors estimate that when the fluorescent substance powder satisfies requirements relating to the above-described circularity, a filling property of the fluorescent substance particles with respect to the cured resin layer is raised, a transmittance of exciting light from a blue LED is reduced, and the chromaticity X can be set to be more large. In addition, when the chromaticity X is set to a large value, color reproducibility of a display element manufactured by using the CASN-based fluorescent substance can be improved.

An average aspect ratio of the fluorescent substance particles having a particle size of 1 μm or greater among the CASN-based fluorescent substance particles may be 1.275 or less.

A main crystal phase constituting the CASN-based fluorescent substance may have the same structure as in a CaAlSiN₃ crystal phase.

The fluorescent substance powder is expressed by a general formula of (CaₓSr_{y}Eu_{z})AlSiN₃, and in the general formula, conditions of 0≤x<1, 0<y<1, and 0<z<1 may be satisfied.

A wavelength of a light-emission peak of the fluorescent substance powder may be 605 nm to 670 nm.

According to an aspect of the present disclosure, there is provided a light-emitting device including: a light-emitting element that emits primary light; and a wavelength converter that absorbs a part of the primary light and emits secondary light having a wavelength longer than a wavelength of the above-described primary light. The wavelength converter contains the fluorescent substance powder.

Since the light-emitting device includes the above-described fluorescent substance powder as a wavelength converter, excellent color reproducibility can be exhibited.

### Advantageous Effects of Invention

According to the present disclosure, it is possible to provide a fluorescent substance powder containing a red-fluorescent substance which is capable of exhibiting large chromaticity X of a cured resin layer when being dispersed in a resin to form the cured resin layer. In addition, according to the present disclosure, it is possible to provide a light-emitting device that includes the above-described fluorescent substance powder and is capable of exhibiting excellent color reproducibility.

### BRIEF DESCRIPTION OF DRAWINGS

FIG. 1 is a view illustrating a distribution of circularity and an equivalent circle diameter of fluorescent substance particles constituting a fluorescent substance powder in Example 1.

FIG. 2 is a view illustrating a distribution of circularity and an equivalent circle diameter of fluorescent substance particles constituting a fluorescent substance powder in Comparative Example 1.

### DESCRIPTION OF EMBODIMENTS

Hereinafter, an embodiment of the present disclosure will be described. However, the following embodiment is illustrative only for explanation of the present disclosure, and the present disclosure is not limited to the following contents.

Materials exemplified in this specification can be used alone or in combination of two or more kinds unless otherwise stated. In a case where a plurality of materials corresponding to each component in a composition exist, the content of each component in the composition represents a total amount of the plurality of materials existing in the composition unless otherwise stated. In this specification, “process” may be an independent process or may be processes performed simultaneously.

An embodiment of the fluorescent substance powder is a powder containing a plurality of CASN-based fluorescent substance particles. The fluorescent substance powder represents an aggregate of fluorescent substance particles. The fluorescent substance powder may be an aggregate constituted by CASN-based fluorescent substance particles.

The CASN-based fluorescent substance represents a CASN fluorescent substance, an SCASN fluorescent substance, or a fluorescent substance having the same crystal structure as in the fluorescent substances. The fluorescent substance powder is expressed by a general formula of (CaₓSr_{y}Eu_{z})AlSiN₃, and in the general formula, conditions of 0≤ x<1, 0<y<1, and 0<z<1 may be satisfied. A main crystal phase of the CASN-based fluorescent substance has the same crystal structure as in a CaAlSiN₃ crystal phase and the CASN-based fluorescent substance is expressed by a general formula of (CaₓSr_{y}Eu_{z})AlSiN₃. In the general formula, conditions of 0≤ x<1, 0<y<1, and 0<z<1 may be satisfied. The CASN-based fluorescent substance may include a different phase within a range not deteriorating the gist of the present disclosure in addition to the main crystal phase.

The crystal structure of the fluorescent substance particles can be confirmed by a powder X-ray diffraction method. In addition, the contents of Ca (calcium), Sr (strontium), Eu (europium), Al (aluminum), Si (silicon), and N (nitrogen) in a composition of the fluorescent substance particles can be determined by subjecting a measurement target to pressurization and acid decomposition to prepare a sample solution and by performing quantitative analysis using ICP emission spectrometer on the prepared sample solution. Note that, since an element composition in the fluorescent substance particles corresponds to the proportion of each element in the preparation when manufacturing the fluorescent substance particles, the element composition of the fluorescent substance particles can also be estimated from a raw material composition.

In the CASN-based fluorescent substance particles in the fluorescent substance powder, in an aggregate of the fluorescent substance particles, average circularity (average value of circularity) of fluorescent substance particles having a particle size of 1 μm or greater is set to be high, and a standard deviation of the circularity relating to fluorescent substance particles having a particle size of 1 μm or greater is set to be suppressed to be relatively small. The average circularity of the fluorescent substance particles having a particle size of 1 μm or greater among the CASN-based fluorescent substance particles is 0.820 or more, and the standard deviation of the circularity is less than 0.080.

A lower limit value of the average circularity of the fluorescent substance particles having a particle size of 1 μm or greater among the CASN-based fluorescent substance particles may be, for example, 0.823 or greater, 0.824 or greater, 0.825 or greater, or 0.830 or greater. When the lower limit value of the average circularity is within the above range, in a case where the fluorescent substance particles are dispersed in a resin to form a cured resin layer, a filling property of the fluorescent substance particles with respect to the cured resin layer can be raised, a transmittance of exciting light from a light source such as a blue LED can be reduced, and a value of chromaticity X can be set to be more large. An upper limit value of the average circularity of fluorescent substance particles having a particle size of 1 μm or greater among the CASN-based fluorescent substance particles may be, for example, 1.000 or less, 0.980 or less, 0.950 or less, 0.900 or less, or 0.850 or less. The average circularity of the fluorescent substance particles having a particle size of 1 μm or greater among the CASN-based fluorescent substance particles may be adjusted within the above-described range, and may be, for example, 0.820 to 1.000, 0.830 to 0.950, or 0.830 to 0.850.

An upper limit value of the standard deviation of the circularity of the fluorescent substance particles having a particle size of 1 μm or greater among the CASN-based fluorescent substance particles may be, for example, 0.075 or less, 0.070 or less, 0.065 or less, 0.060 or less, 0.058 or less, 0.055 or less, 0.053 or less, 0.052 or less, or 0.050 or less. When the upper limit value of the standard deviation is within the above-described range, the fluorescent substance powder has more uniform circularity, and in a case where the fluorescent substance particles are dispersed in the resin to form the cured resin layer, the filling property of the fluorescent substance particles with respect to the cured resin layer can be raised, the transmittance of exciting light from the light source such as a blue LED can be reduced, and the value of the chromaticity X can be set to be more large. Although a lower limit value of the standard deviation of the circularity of the fluorescent substance particles having a particle size of 1 μm or greater among the CASN-based fluorescent substance particles is not particularly limited, the lower limit value may be, typically, 0.020 or greater, 0.030 or greater, 0.040 or greater, or 0.045 greater. The standard deviation of the circularity of the fluorescent substance particles having a particle size of 1 μm or greater among the CASN-based fluorescent substance particles may be adjusted within the above-described range, and may be, for example, 0.020 or greater and less than 0.080, 0.030 to 0.075, 0.040 or 0.060, or 0.045 to 0.058.

The circularity in this specifications is a value calculated by the following expression when a projection area of the fluorescent substance particles is set as A, and a peripheral length of the fluorescent substance particles is set as P. Note that, the peripheral length represents a length of a contour line in a projection image of the fluorescent substance particles. In measurement of the circularity, a particle shape image analyzer can be used. As the particle shape image analyzer, for example, “PITA-04” (trade name, manufactured by SEISHIN ENTERPRISE Co., Ltd.) or the like can be used. Note that, in this specifications, description of “a particle size of 1 μm or greater” is defined as a numerical value that can be detected by a measurement device when measuring properties such as the circularity, and is set to measure a desired physical value with sufficient accuracy. The measurement device may be set so that particles having a particle size of 1 μm or greater are set as a measurement target. Particles having a particle size of less than 1 μm may not be detected depending on a measurement device.

$$Circularity = [ 4 π \times A ] / {P}^{2}$$

An upper limit value of an average aspect ratio (an average value of an aspect ratio) of the fluorescent substance particles having a particle size of 1 μm or greater among the CASN-based fluorescent substance particles may be, for example, 1.275 or less, 1.250 or less, 1.230 or less, 1.210 or less, 1.200 or less, or 1.150 or less. When the upper limit value of the average aspect ratio is within the above-described range, in a case where the fluorescent substance particles are dispersed in the resin to form the cured resin layer, the filling property of the fluorescent substance particles with respect to the cured resin layer can be raised, the transmittance of exciting light from the light source such as a blue LED can be reduced, and the value of the chromaticity X can be set to be large. A lower limit value of the average aspect ratio of the fluorescent substance particles having a particle size of 1 μm or greater among the CASN-based fluorescent substance particles may be, for example, 1.000 or greater, 1.010 or greater, 1.020 or greater, 1.030 or greater, or 1.040 or greater. The average aspect ratio of the fluorescent substance particles having a particle size of 1 μm or greater among the CASN-based fluorescent substance particles may be adjusted within the above-described range, and may be, for example, 1.000 to 1.275, 1.040 to 1.210, or 1.040 to 1.150.

An upper limit value of an average equivalent circle diameter of the fluorescent substance particles having a particle size of 1 μm or greater among the CASN-based fluorescent substance particles may be, for example, 15.0 μm or less, 10.0 μm or less, 7.0 μm or less, or 5.0 μm or less. When the upper limit value of the average equivalent circle diameter is within the above-described range, the fluorescent substance powder is useful when being used for a micro LED display. A lower limit value of the average equivalent circle diameter of the fluorescent substance particles having a particle size of 1 μm or greater among the CASN-based fluorescent substance particles may be, for example, 0.1 μm or greater, 0.2 μm or greater, 0.3 μm or greater, 0.4 μm or greater, 0.6 μm or greater, 0.8 μm or greater, 1.0 μm or greater, 1.5 μm or greater, or 1.8 μm or greater. When the lower limit value of the average equivalent circle diameter is within the above-described range, an absorption rate with respect to exciting light can be further improved even when the fluorescent substance powder is dispersed in a cured resin. The average equivalent circle diameter of the fluorescent substance particles having a particle size of 1 μm or greater among the CASN-based fluorescent substance particles may be adjusted within the above-described range, and may be, for example, 0.1 μm to 15.0 μm, 0.4 μm to 5.0 μm, 1.0 μm to 5.0 μm, or 1.5 μm to 5.0 μm.

The average circularity, the standard deviation of the circularity, the average aspect ratio, and the average equivalent circle diameter in this specification are values determined by image analysis of the fluorescent substance particles having a particle size of 1 μm or greater, and are values measured by the following method. First, a fluorescent substance powder that is a measurement target is put into purified water containing a surfactant, and an ultrasonic treatment is performed for 1 minute to prepare a dispersion solution, and the dispersion solution is set as a measurement sample. With respect to the dispersion solution, an observation image of the fluorescent substance particles is acquired by using the particle shape image analyzer in a state in which a suction pump speed is set to 3000 Hz and a lens magnification is set to 10 times during measurement. Circularity, an aspect ratio, and an equivalent circle diameter are determined from obtained particle image data. Note that, the number of fluorescent substance particles to be observed is set to 5000, and each average value is set to an arithmetic average value of data acquired with respect to 5000 pieces. Note that, as the particle shape image analyzer, for example, “PITA-04” (trade name, manufactured by SEISHIN ENTERPRISE Co., Ltd.) can be used.

The above-described fluorescent substance powder is useful, for example, as a red-fluorescent substance. A wavelength of a light-emission peak of the above-described fluorescent substance powder may be, for example, 605 nm to 670 nm, 620 nm to 650 nm, or 630 nm to 650 nm.

A lower limit value of the chromaticity X of the above-described fluorescent substance powder can be set to, for example, 0.620 or greater, 0.630 or greater, 0.650 or greater, 0.660 or greater, 0.663 or greater, or 0.665 or greater. In addition, an upper limit value of the chromaticity X of the above-described fluorescent substance powder can be set to, for example, 0.72 or less, 0.700 or less, or 0.690 or less.

The above-described fluorescent substance powder can be used alone, or in combination with other fluorescent substances. Since the fluorescent substance powder according to the present disclosure exhibits excellent chromaticity X, the fluorescent substance powder can be suitably used, for example, in a light-emitting device such as an LED, a display device, and the like. The fluorescent substance powder can be used in a state of being dispersed in a cured resin. The cured resin is not particularly limited, and for example, a resin or the like that is used as a sealing resin of the light-emitting device or the like can be used.

An embodiment of the light-emitting device is a light-emitting device including a light-emitting element that emits primary light, and a wavelength converter that absorbs a part of the primary light and emits secondary light having a wavelength longer than a wavelength of the primary light. The wavelength converter includes the above-described fluorescent substance powder. The light-emitting element that emits the primary light may be, for example, an InGaN blue LED or the like. The light-emitting element and the wavelength converter may be dispersed in a sealing resin or the like.

The described-above fluorescent substance powder can be manufactured directly, for example, by the following method, or can also be prepared by mixing fluorescent substance particles having different particle sizes with each other. An example of the method of manufacturing the fluorescent substance powder includes a process (firing process) of heating a mixed powder including a calcium source, an aluminum source, a silicon source, a nitrogen source, and a europium source to obtain a fired object, a process (annealing process) of heating the fired object at a temperature lower than a heating temperature in the firing process to obtain an annealed object, a process (pulverization process) of pulverizing the annealed process to obtain a pulverized object, a process (classification process) of reducing the content of fine particles in the pulverized object, and a process (acid treatment process) of subjecting the pulverized object to an acid treatment to obtain a fluorescent substance powder.

The mixed powder in the firing process may contain the calcium source, the aluminum source, the silicon source, the nitrogen source, and the europium source, and may contain other components. Examples of the other components include a strontium source and the like. Here, the calcium source, the aluminum source, the silicon source, the nitrogen source, the europium source, and the strontium source represent compounds and elementary substances which serve as supply sources of Ca (calcium), Al (aluminum), Si (silicon), N (nitrogen), Eu (europium), and Sr (strontium), respectively. The compounds represent compounds including the elements to be supplied as a constituent element. Here, for example, in a case where europium nitride is blended to the mixed powder, the europium nitride serves as not only a nitrogen source but also a europium source.

A compound (calcium compound) including Ca as a constituent element, a compound (aluminum compound) including Al as a constituent element, a compound (silicon compound) including Si as a constituent element, a compound (europium compound) including Eu as a constituent element, and a compound (strontium compound) including Sr as a constituent element may be any one of a nitride, an oxide, an oxynitride, and a hydroxide, but preferably the nitride.

Examples of the calcium compound include calcium nitride (Ca₃N₂) and the like.

Examples of the aluminum compound include aluminum nitride (AlN), aluminum oxide (Al₂O₃), aluminum hydroxide (Al(OH)₃), and the like.

Examples of the silicon compound include silicon nitride (Si₃N₄), silicon oxide (SiO₂), and the like. As the silicon nitride, it is preferable to use one with a high a fraction. The a fraction of the silicon nitride may be, for example, 80% by mass or greater, 90% by mass or greater, or 95% by mass or greater. When the a fraction of the silicon nitride is within the above-described range, growth of primary particles of an inorganic compound can be promoted.

Examples of the europium compound include an oxide of europium (europium oxide), a nitride of europium (europium nitride), a halide of europium, and the like. Examples of the halide of europium include europium fluoride, europium chloride, europium bromide, europium iodide, and the like. The europium compound preferably contains europium oxide. A valence of europium in the europium compound may be divalent or trivalent, and preferably divalent.

Europium constituting the europium compound may be dissolved in the CASN-based fluorescent substance through the firing process, may be volatilized and removed in the heating process, or may remain as a different phase component. The different phase component containing europium may be the cause for a decrease in luminance of the fluorescent substance powder, but the component can be reduced or removed by an acid treatment to be described later. In addition, when a different phase has a small absorption rate with respect to exciting light, the different phase may remain in the fluorescent substance powder, and europium may be contained in the different phase.

Examples of the strontium compound include strontium nitride (Sr₃N₂) and the like.

The mixed powder can be prepared by weighing and mixing respective compounds. A dry mixing method or a wet mixing method may be used in the mixing. The dry mixing method may be a method of mixing respective components by using, for example, a small mill mixer, a V-type mixer, a locking mixer, a ball mill, a vibration mill, or the like. For example, the wet mixing method may be a method of preparing a solution or slurry by adding a solvent such as water or a dispersion medium to the respective components, mixing the respective components, and removing the solvent or the dispersion medium. When preparing the mixed powder, after mixing the compounds by a device or the like, aggregates can be removed by using a sieve or the like as necessary. From the viewpoint of suppressing oxidation of the compounds constituting the mixed powder, and suppressing mixing of impurities into the mixed powder, the mixing process is preferably performed under an inert gas atmosphere. Examples of the inert gas atmosphere include a rare gas atmosphere and a nitrogen gas atmosphere, but the nitrogen gas atmosphere is preferable. The preparation of the mixed powder is preferably performed under a nitrogen atmosphere and under an environment with low relative humidity.

Heating in the firing process and the annealing process may be performed, for example, by filling a mixed powder and the like to be heated into a container with a heat-resistant lid and by heating the container. As the heat-resistance container, for example, a tungsten container or the like can be used. For example, an electric furnace or the like can be used in the heating.

In the firing process, the above-described mixed powder is heated to obtain a fired object.

A firing temperature in the firing process is preferably constant throughout the process. The firing temperature in the firing process may be, for example, 1450° C. or higher, 1500° C. or higher, 1600° C. or higher, 1800° C. or higher, or 1900° C. or higher. When a lower limit value of the firing temperature is within the above-described range, growth of primary particles of the CASN-based fluorescent substance can be promoted, and a light absorption rate and quantum efficiency of the CASN-based fluorescent substance particles can be further improved. According to this, a full width at half maximum at a fluorescent peak of the obtained fluorescent substance powder can be further decreased. The firing temperature in the firing process may be, for example, 2100° C. or lower, 2050° C. or lower, or 2000° C. or lower. When an upper limit value of the firing temperature is within the above-described range, decomposition of primary particles of the CASN-based fluorescent substance can be more sufficiently suppressed, excessive growth of the primary particles of the CASN-based fluorescent substance can be suppressed, and adjustment of the circularity and the equivalent circle diameter becomes easy. The firing temperature in the firing process can be adjusted within the above-described range, and may be, for example, 1450° C. to 2100° C., 1500° C. to 2100° C., or 1500° C. to 2000° C.

In the firing process, a temperature rising rate, a firing time, a pressure during firing, and the like can be appropriately adjusted in correspondence with components, a composition ratio, and the amount of the mixed powder, and the like.

A lower limit value of the firing time in the firing process may be, for example, 0.5 hours or longer, 1.0 hour or longer, 1.5 hours or longer, 3.0 hours or longer, or 4.0 hours or longer. An upper limit value of the firing time in the firing process may be, for example, 30.0 hours or shorter, 20.0 hours or shorter, 15.0 hours or shorter, 12.0 hours or shorter, 10.0 hours or shorter, 8.0 hours or shorter, or 5.0 hours or shorter. The firing time in the firing process can be adjusted within the above-described range, and may be, for example, 0.5 hours to 30.0 hours, 3.0 hours to 30.0 hours, 4.0 hours to 12.0 hours, or 4.0 hours to 8.0 hours.

The firing process is preferably performed under an atmosphere containing at least one kind selected from the group consisting of a rare gas and an inert gas. For example, the rare gas may contain argon, helium, and the like, may contain argon, or may consist of argon. For example, the inert gas may contain nitrogen and the like, or may consist of nitrogen.

The firing process may be performed under an atmospheric pressure, or under pressurization. In a case of performing the firing process under a pressurized environment, a lower limit value of a pressure during firing in the firing process may be, for example, 0.025 MPaG or greater, 0.03 MPaG or greater, 0.050 MPaG or greater, 0.100 MPaG or greater, 0.150 MPaG or greater, 0.300 MPaG or greater, 0.500 MPaG or greater, 0.600 MPaG or greater, 0.800 MPaG or greater, or 0.830 MPaG or greater. An upper limit value of the pressure during firing in the firing process may be, for example, 10.00 MPaG or less, 8.00 MPaG or less, 5.00 MPaG or less, 3.00 MPaG or less, or 1.00 MPaG or less. The pressure in the firing process can be adjusted within the above-described range, and may be, for example, 0.025 MPG to 10.00 MPG, 0.030 MPaG to 8.00 MPaG, 0.030 MPaG to 5.00 MPaG, or 0.030 MPaG to 1.00 MPaG. The pressure in this specification represents a gauge pressure.

The annealing process is a process of obtaining an annealed object by heating the fired object at a temperature lower than the heating temperature in the firing process. From the viewpoint of improving a heating effect in the annealing process, in a case where the fired object is obtained as a lump, the fired object may be applied to the annealing process after being subjected to crushing, classification, and the like. For example, crushing and classification conditions may be set to conditions described in a pulverization process and a classification process to be described later.

The heating temperature in the annealing process is preferably constant throughout the process. An upper limit value of the heating temperature in the annealing process is adjusted to be equal to or lower than the heating temperature in the firing process, and may be, for example, 1700° C. or lower, 1650° C. or lower, 1600° C. or lower, 1550° C. or lower, 1500° C. or lower, 1450° C. or lower, or 1400° C. or lower. When the upper limit value of the temperature is within the above-described range, an oxidation reaction of a light-emission center is suppressed, and a deterioration of optical characteristics can be more sufficiently prevented. A lower limit value of the heating temperature in the annealing process may be, for example, 1200° C. or higher, 1250° C. or higher, or 1300° C. or higher. When the lower limit value of the temperature is set within the above-described range, deformation or a defect in a crystal phase is reduced due to rearrangement of elements constituting the crystal phase included in the fired object, and the like, and light-emission efficiency of the obtained fluorescent substance powder can be further improved. In addition, when the lower limit value of the temperature is set within the above-described range, deformation or a defect of a crystal is reduced, and transparency of the CASN-based fluorescent substance particles can also be improved. Although a different phase may be formed by the process, the different phase can be sufficiently removed by a classification process, and an acid treatment process, and the like to be described later. The heating temperature in the annealing process can be adjusted within the above-described range, and may be, for example, 1200° C. to 1700° C., 1300° C. to 1600° C., or 1300° C. to 1400° C.

A lower limit value of the heating time in the annealing process may be, for example, 1.5 hours or longer, 3.0 hours or longer, 4.0 hours or longer, or 5.0 hours or longer. An upper limit value of the heating time in the annealing process may be, for example, 12.0 hours or shorter, 11.0 hours or shorter, or 10.0 hours or shorter. The heating time in the annealing process can be adjusted within the above-described range, and may be, for example, 3.0 hours to 12.0 hours, or 5.0 hours to 10.0 hours.

The annealing process may be performed under an atmosphere containing at least one kind selected from the group consisting of a rare gas, a reducing gas, and an inert gas, or may be performed under a non-oxidizing atmosphere such as in vacuum other than pure nitrogen. The rare gas may contain, for example, argon, helium, and the like, may contain argon, or may consist of argon. The reducing gas may contain, for example, ammonia, hydrocarbon, carbon monoxide, hydrogen, and the like, may contain hydrogen, or may consist of hydrogen. The inert gas may contain, for example, nitrogen and the like, or may consist of nitrogen. The annealing process is preferably performed under a hydrogen gas atmosphere, or an argon atmosphere.

The annealing process may be performed under an atmospheric pressure, or under pressurization. In a case where the annealing process is performed under the pressurized environment, a lower limit value of a pressure of an atmosphere under which the annealing process is performed may be, for example, 0.01 MPaG or higher, or 0.02 MPaG or higher. An upper limit value of the pressure of the atmosphere under which the annealing process is performed may be, for example, 10.00 MPaG or less, 8.00 MPaG or less, or 5.00 MPaG or less. The pressure in the firing process can be adjusted within the above-described range, and may be, for example, 0.02 MPaG to 10.00 MPaG.

The pulverization process is, for example, a process of crushing or pulverizing the annealed object in the annealing process, adjusting a particle size, and improving the circularity of the CASN-based fluorescent substance particles. When crushing or pulverizing the annealed object, from the viewpoint of suppressing occurrence of scratches and cracks on surfaces of the fluorescent substance particles, generation of defects inside the fluorescent substance particles, and the like, the crushing or pulverization is preferably performed under gentle conditions.

In the pulverization process, a ball mill is preferably used as a pulverizer. The pulverization process is preferably performed by wet ball mill pulverization in which an aqueous solution such as ion exchanged water is present.

The aqueous solution may contain other components of the ion exchanged water. Examples of the other components contained in the aqueous solution include an organic solvent such as low grade alcohol and acetone, and a dispersant such as sodium hexametaphosphate, sodium pyrophosphate (Napp), trisodium phosphate (TSP), and a surfactant, and the like.

A lower limit value of a blending amount of the aqueous solution may be, for example, 0.1% by volume or greater, 0.3% by volume or greater, 0.5% by volume or greater, or 1.0% by volume or greater on the basis of a total volume of the annealed object. When the lower limit value of the blending amount of the aqueous solution is within the above-described range, the annealed object can be pulverized under more gentle conditions, and a deterioration of the optical characteristics as a fluorescent substance can be further suppressed. An upper limit value of the blending amount of the aqueous solution may be, for example, 60% by volume or less, 50% by volume or less, 45% by volume or less, or 40% by volume or less on the basis of a total volume of the annealed object. When the upper limit value of the blending amount of the aqueous solution is set within the above-described range, a force applied to pulverization of the annealed object by balls is improved, and thus the circularity of the CASN-based fluorescent substance particles can be more raised. The blending amount of the aqueous solution may be adjusted within the above-described range, and may be, for example, 1.0% by volume to 45% by volume on the basis of a total volume of the annealed object.

As balls used in the ball mill, zirconia balls can be used. A diameter of the balls may be, for example, 0.2 mm to 20.0 mm, 0.5 mm to 10.0 mm, or 1.0 mm to 5.0 mm. When deviating from the condition, the average circularity and the standard deviation of the circularity are less likely to be set within a predetermined range, and thus the obtained fluorescent substance powder is less likely to exhibit desired color reproducibility.

A ball filling rate in a container in a case of the ball mill can be adjusted in accordance with the circularity and a particle size such as the equivalent circle diameter which are required for the fluorescent substance powder.

A lower limit value of pulverizing time (pulverization time) in the pulverization process may be, for example, 1 hour or longer, 2 hours or longer, 3 hours or longer, 4 hours or longer, 5 hours or longer, 6 hours or longer, 7 hours or longer, 8 hours or longer, 9 hours or longer, 10 hours or longer, or 12 hours or longer. When the lower limit value of the pulverization time is set within the above-described range, a sufficiently fine pulverized object can be obtained, and acid treatment efficiency in the subsequent acid treatment process can be further improved. An upper limit value of the pulverization time may be, for example, 80 hours or shorter, 70 hours or shorter, 60 hours or shorter, 40 hours or shorter, 30 hours or shorter, or 24 hours or shorter. When the upper limit value of the pulverization time is set within the above-described range, occurrence of scratches and cracks on surfaces of the fluorescent substance particles, generation of defects inside the fluorescent substance particles, and the like due to excessive pulverization of the annealed object can be more sufficiently suppressed. The pulverization time may be adjusted within the above-described range, and may be, for example, 1 hour to 60 hours, 4 hours to 40 hours, or 10 hours to 24 hours.

The classification process is a process of removing fine particles in the pulverized object which are generated by the pulverization process.

In the classification process, for example, a decantation method may be used. The classification process is performed by putting the pulverized object into a dispersion medium to prepare a dispersion solution, stirring the dispersion solution, precipitating the fluorescent substance powder in the dispersion solution, and removing a supernatant. After removing the supernatant, the precipitate is filtered and dried to obtain a fluorescent substance powder from which fine particles are removed. In the classification process, preparation of the above-described dispersion solution and removal of the supernatant may be repetitively performed. For example, the dispersion medium may be an aqueous solution containing ion exchanged water or the like. The dispersion solution may further contain, for example, an organic solvent such as low-grade alcohol and acetone, and a dispersant such as sodium hexametaphosphate, sodium pyrophosphate (Napp), trisodium phosphate (TSP), and a surfactant in addition to the dispersion medium.

In the preparation of the dispersion solution, for example, a dispersion treatment using ultrasonic waves is preferably used. When using ultrasonic waves, removal of the fine particles in the pulverized object can be performed with more accuracy and in an efficient manner. According to this, aggregation of the fine particles and the like in the obtained fluorescent substance powder can be further suppressed.

After preparing the dispersion solution, the fluorescent substance particles are precipitated and collected by allowing the dispersion solution to stand still or by centrifugating the dispersion solution. Particles of the fine particles to be removed can be arbitrarily determined, and precipitation conditions for removing the fine particle can be determined by using Stokes equation shown in the following Expression (1). The fine particles may be, for example, a particle group having an average particle size of less than 0.4 μm.

$${v}_{s} = [ {D}_{p}^{2} ( {ρ}_{p} - {ρ}_{f} ) g ] / 18 η \qquad Expression ( 1 )$$

In Expression (1), vₛ represents a terminal velocity [unit: cm/s], Dₚ represents a particle size [unit: cm] of the fluorescent substance particles, ρₚ represents a density of the fluorescent substance particles [unit: g/cm³], ρ_{f} represents a density of a dispersion medium (fluid) [unit: g/cm³], g represents gravitational acceleration [unit: cm/s²], and η represents viscosity of the dispersion medium (fluid) [unit: g/(cm·s)].

For example, when the dispersion solution is allowed to stand still to cause precipitation to occur, first, a sedimentation distance is arbitrarily determined and a particle size of fine particles to be removed is determined. Next, a target particle size Dₚ to be removed, gravitational acceleration g of 1 G, and various values specific to the fluorescent substance particles and the dispersion medium (the density ρₚ of the fluorescent substance particles, the density ρ_{f} of the dispersion medium, and the viscosity η of the dispersion medium) are substituted for the Stokes equation expressed by Expression (1) to calculate the terminal speed vₛ as a sedimentation speed. Stand-still time is calculated from the calculated sedimentation speed and the sedimentation distance. After elapse of the stand-still time calculated as described above from preparation of the dispersion solution, the supernatant is removed. According to this, it is possible to remove target fine particles to be removed and fine particles having a particle size smaller than that of the target fine particles to be removed.

In addition, when precipitation is caused to occur in the dispersion solution by using a centrifugal separator, first, a sedimentation distance and sedimentation time are set, and a particle size of fine particles to be removed is determined. Next, a target particle size Dₚ to be removed, a terminal speed vₛ, and various values specific to the fluorescent substance particles and the dispersion medium (the density ρₚ of the fluorescent substance particles, the density ρ_{f} of the dispersion medium, and the viscosity η of the dispersion medium) are substituted for the Stokes equation expressed by Expression (1) to calculate the gravitational acceleration g. From a relationship between the number of revolutions specific to the centrifugal separator, and the gravitational acceleration g calculated as described above, the number of revolutions to be performed by the centrifugal separator is determined. After preparing the dispersion solution, centrifugal separation is performed by the sedimentation time set first on the basis of the number of revolutions calculated as described above, and then a supernatant is removed. According to this, it is possible to remove fine target particles to be removed and fine particles having a particle size smaller than that of the target fine particles to be removed.

The classification process may be performed by repeating the decantation method a plurality of times.

The acid treatment process is a process of reducing the content of impurities which do not contribute to light emission by treating the fluorescent substance powder with an acid.

Examples of the acid include hydrochloric acid, hydrofluoric acid, sulfuric acid, phosphoric acid, nitric acid, and the like. The acid may include at least one kind selected from the group consisting of the hydrochloric acid, the hydrofluoric acid, the sulfuric acid, the phosphoric acid, and the nitric acid, and may be the mixed acid. As the acid, hydrochloric acid is preferable. A concentration of the acid may be, for example, 0.5 M to 1 M.

The acid treatment process is performed by bringing the pulverized object into contact with the above-described acid. Specifically, the above-described pulverized object is put into an aqueous solution containing the acid to prepare a dispersion solution, and a treatment is performed for predetermined time while stirring the dispersion solution. A lower limit value of the stirring time is, for example, 0.15 hours or longer, 0.50 hours or longer, or 1.00 hour or longer. An upper limit value of the stirring time may be, for example, 6.00 hours or shorter, 3.00 hours or shorter, or 1.50 hours or shorter.

In the acid treatment process, the acid treatment may be performed in a state in which the aqueous solution is cooled or heated. A temperature of the aqueous solution at this time may be, for example, 20° C. to 90° C., 40° C. to 90° C., or 50° C. to 70° C. After the acid treatment, the fluorescent substance powder may be washed with water to remove the acid and may be dried. A drying temperature may be, for example, 100° C. to 120° C. Drying time may be, for example, approximately 12 hours.

Hereinbefore, several embodiments have been described, but the present disclosure is not limited to the embodiments at all. In addition, description contents related to the above-described embodiments can be applicable to each other.

### EXAMPLES

Hereinafter, the contents of the present disclosure will be described in more detail with reference to Examples and Comparative Examples. However, the present disclosure is not limited to the following Examples.

### Example 1

### <Method of Manufacturing Fluorescent Substance Powder>

In a glove box maintained in a nitrogen atmosphere, 25.7 parts by mass of α-type silicon nitride (Si₃N₄, manufactured by Ube Industries, Ltd., SN-E10 grade), 22.5 parts by mass of aluminum nitride (AlN, manufactured by Tokuyama Corporation, E grade), 3.0 parts by mass of calcium nitride (Ca₃N₂, manufactured by Materion Corporation), 43.1 parts by mass of strontium nitride (Sr₃N₂, purity: 2 N, manufactured by Kojundo Chemical Laboratory. Co., Ltd.), and 5.8 parts by mass of europium oxide (Eu₂O₃, manufactured by Shin-Etsu Chemical Co., Ltd., RU grade) were collected in a container and were dry-mixed to obtain a raw material powder (mixed powder).

In the glove box, the raw material powder was filled in a container with a tungsten lid. The container with the lid was taken out from the glove box, the container was disposed in an electric furnace provided with a carbon heater, and the container was sufficiently vacuum evacuated until a pressure inside the electric furnace became 0.1 PaG or less. The temperature inside the electric furnace was raised until reaching 850° C. while continuing the vacuum evacuation. After reaching 850° C., a nitrogen gas was introduced into the electric furnace, and the pressure inside the electric furnace was adjusted to be 0.85 MPaG. Then, the temperature inside the electric furnace was raised until reaching 1930° C. under a nitrogen gas atmosphere, and heating was performed for 4 hours in a state of maintaining the reached temperature (firing process). Then, heating was terminated, and cooling was performed to room temperature. After cooling to room temperature, a lump was collected from the container. The collected lump was crushed and pulverized by a jet mill to obtain a fired powder.

The fired powder was filled in a container with a tungsten lid. The container with the lid was disposed in an electric furnace provided with a carbon heater, and was sufficiently vacuum evacuated until a pressure inside the electric furnace became 0.1 PaG or less. The temperature inside the electric furnace was raised until reaching 850° C. while continuing the vacuum evacuation. After reaching 850° C., an argon gas was introduced into the electric furnace, and the pressure inside the electric furnace was adjusted to be 0.03 MPaG. Then, heating was performed for 4 hours under an argon gas atmosphere in a state of maintaining the temperature inside the electric furnace at 1350° C. (annealing process). Then, heating was terminated, and cooling was performed to room temperature. After cooling to room temperature, a lump was collected from the container. The collected lump was crushed by a mortar to obtain an annealed powder.

The obtained annealed powder was put into a ball mill, and a pulverization treatment was performed for 15 hours in a wet manner to prepare a pulverized object (pulverization process). At this time, as balls, zirconia balls having a diameter of 5 mm were used, and the ion exchanged water was adjusted so that a blending amount becomes 3.13% by volume on the basis of a total volume of the annealed powder. A red powder was obtained as the pulverized object.

Next, the red powder was immersed in 0.5 M hydrochloric acid so that a concentration of the powder becomes 26.7% by mass, and an acid treatment of stirring the resultant solution for 1 hour while heating the solution was performed (acid treatment process). After the acid treatment, stirring was terminated, and the powder was allowed to be precipitated, and a supernatant and fine powder generated in the acid treatment were removed. Then, distilled water was further added and stirring was performed again. After terminating stirring, a powder was precipitated, and a supernatant and fine powder were removed. The operation was repeated until pH of the aqueous solution became 8 or less and the supernatant solution became transparent, the obtained precipitate was filtered and dried under air atmosphere to obtain a fluorescent substance powder.

### Example 2

A fluorescent substance powder was obtained in a similar manner as in Example 1 except that the pulverized object obtained by the pulverization process was subjected to a classification treatment to be described later to reduce fine particles and to obtain a red powder. The pulverized object was dispersed in aqueous solution containing 0.05% by mass of sodium hexametaphosphate to prepare a dispersion solution, and the dispersion solution was filled in a cylindrical container including an intake port at a predetermined height from the bottom, and a supernatant was removed by a decantation method to remove fine particles from the pulverized object (classification process). Note that, the classification process was performed by a method in which setting is made to remove particles having a particle size of 1.5 μm or less, the Stokes equation is used, sedimentation time of the fluorescent substance particles is calculated, and a supernatant solution with a predetermined height or greater is removed when reaching predetermined time from initiation of sedimentation. The treatment by the decantation method was performed a plurality of times, the precipitate was filtered and dried to obtain a red powder from which the fine particles were removed (pulverized object with reduced fine particles).

### Example 3

A fluorescent substance powder was obtained in a similar manner as in Example 2 except that the pulverization time in the pulverization process was changed to 20 hours.

### Example 4

A fluorescent substance powder was obtained in a similar manner as in Example 2 except that setting of the classification process is changed to remove particles having a particle size of 2.0 μm or less.

### Example 5

A fluorescent substance powder was obtained in a similar manner as in Example 2 except that blending ratios of silicon nitride, aluminum nitride, calcium nitride, strontium nitride, and europium oxide were changed as described in Table 1, the firing temperature in the firing process was set to 1550° C., the firing time was set to 12 hours, the pressure of the atmosphere during firing was changed to 0.03 MPaG, the heating temperature in the annealing process was set to 1350° C., the heating time was changed to 4 hours, the diameter of the balls in the pulverization process was set to 1 mm, and the blending amount of the ion exchanged water was changed to be 4.17% by volume.

### Comparative Example 1

A fluorescent substance powder was obtained in a similar manner as in Example 1 except that the pulverization process and the classification process were not performed.

### Comparative Example 2

A fluorescent substance powder was obtained in a similar manner as in Example 1 except that blending ratios of silicon nitride, aluminum nitride, calcium nitride, strontium nitride, and europium oxide were changed as described in Table 1, the firing temperature in the firing process was changed to 1650° C., and the pulverization process and the classification process were not performed.

### Comparative Example 3

A fluorescent substance powder was obtained in a similar manner as in Example 1 except that blending ratios of silicon nitride, aluminum nitride, calcium nitride, strontium nitride, and europium oxide were changed as described in Table 1, the firing temperature in the firing process was set to 1950° C., the firing time was changed to 8 hours, and the pulverization process and the classification process were not performed.

### <Compositional Formula of Fluorescent Substance Powder>

With regard to the fluorescent substance powders obtained in Examples 1 to 5 and Comparative Examples 1 to 3, from a compositional ratio of a raw material composition, it was confirmed that any of the fluorescent substance powders has a composition that is expressed by a general formula of (CaₓSr_{y}Eu_{z})AlSiN₃ and satisfies conditions of 0≤x<1, 0<y<1, and 0<z<1.

### <Confirmation of Crystal Structure in Fluorescent Substance Powder>

With respect to the fluorescent substance powders obtained in Examples 1 to 5 and Comparative Example 1 to 3, X-ray diffraction patterns were acquired by a powder X-ray diffraction method using an X-ray diffraction device (trade name: UltimaIV, manufactured by Rigaku Corporation). A crystal structure was confirmed from the obtained X-ray diffraction patterns. With respect to any of the obtained X-ray diffraction patterns, the same diffraction pattern as in a CaAlSiN₃ crystal was recognized. Note that, in the measurement, CuKα rays (characteristic X-rays) were used.

### <Measurement of Circularity, Average Circularity, Average Aspect Ratio, and Average Equivalent Circle Diameter of Fluorescent Substance Powder>

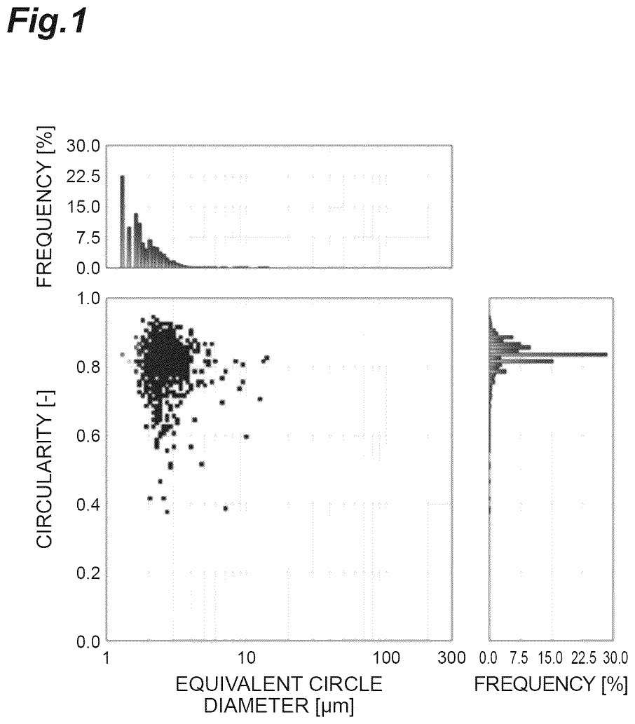

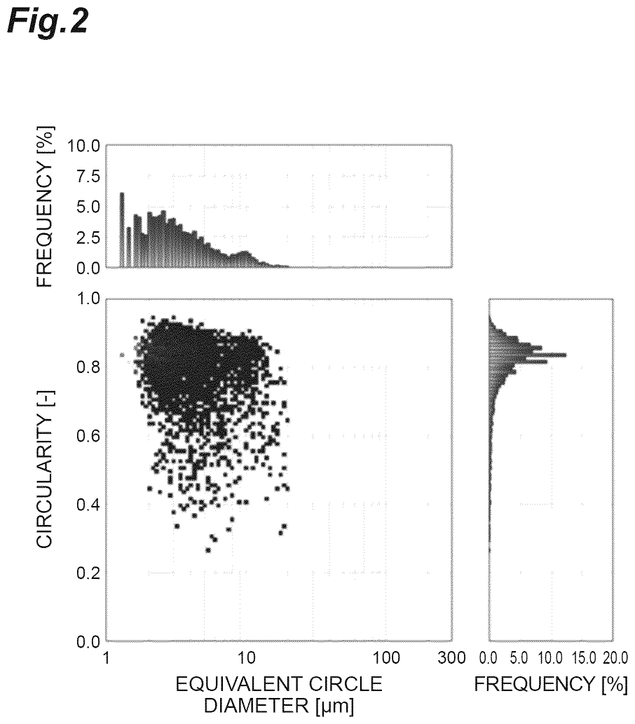

With respect to the fluorescent substance powders obtained in Examples 1 to 5 and Comparative Examples 1 to 3, circularity, an aspect ratio, and an equivalent circle diameter of fluorescent substance particles having a particle size of 1 μm or greater were measured respectively. The fluorescent substance powder was put into purified water containing a surfactant, and an ultrasonic treatment was performed for 1 minute to prepare a dispersion solution, and the dispersion solution was set as a measurement sample. With respect to the dispersion solution, the fluorescent substance particles were observed under conditions in which a suction pump speed was set to 3000 Hz and a lens magnification was set to 10 times during measurement by using a particle shape image analyzer (trade name: PITA-04, manufactured by SEISHIN ENTERPRISE Co., Ltd.). The number of fluorescent substance particles to be observed was set to 5000. The circularity, the average circularity, the average aspect ratio, and the average equivalent circle diameter of the fluorescent substance particles having a particle size of 1 μm or greater were determined from obtained particle image data. With respect to the fluorescent substance powder of Example 1 and the fluorescent substance powder of Comparative Example 1, a distribution diagram of the circularity and the equivalent circle diameter are shown in FIG. 1 and FIG. 2 for reference. Note that, data related to fluorescent substance particles having a particle size of less than 1 μm is not shown in FIG. 1 and FIG. 2.

<Measurement of Optical Absorption Rate, Internal Quantum Efficiency, External Quantum Efficiency, and Light-Emission Peak Wavelength for Light of 455 nm>

Absorption rate (optical absorption rate), internal quantum efficiency, and external quantum efficiency of light in a case of irradiating the fluorescent substance powders obtained in Examples 1 to 5 and Comparative Examples 1 to 3 with exciting light of a wavelength of 455 nm were calculated by the following steps. Results are shown in Table 1.

First, the fluorescent substance powder to be measured was filled in a concave cell so that a surface became smooth, and the cell was attached to an opening of an integrating sphere. Monochromatic light separated to a wavelength of 455 nm from a Xe lamp that is a light-emission source was introduced into the integrating sphere as fluorescent substance exciting light by using optical fibers. The fluorescent substance powder to be measured was irradiated with monochromatic light that is exciting light to measure a fluorescent spectrum. In the measurement, a spectrophotometer (trade name: MCPD-7000, manufactured by Otsuka Electronics Co., Ltd.) was used.

The number of excitation reflected light photons (Qref) and the number of fluorescent photons (Qem) were calculated from the obtained fluorescent spectrum data. The number of excitation reflected light photons was calculated in the same wavelength range as in the number of excitation light photons, and the number of fluorescent photons was calculated in a range of 465 nm to 800 nm. In addition, a standard reflection plate (Spectralon (registered trademark), manufactured by Labsphere) with a reflectance of 99% was attached to the opening of the integrating sphere, and a spectrum of excitating light with a wavelength of 455 nm was measured by the same device. At this time, the number of excitation light photons (Qex) was calculated from a spectrum in a wavelength range of 450 nm to 465 nm.

From the above-described calculated results, an absorption rate of exciting light of 455 nm and internal quantum efficiency in the fluorescent substance powder to be measured were obtained on the basis of the following calculation formulae.

$$Absorption rate of exciting light of 455 nm = ( ( Q ex - Qref ) / Qex ) \times 100$$

$$Internal quantum efficiency = ( Qem / ( Qex - Qref ) ) \times 100$$

$$External quantum efficiency = ( Qem / Qex ) \times 100$$

Note that, a relational expression of the external quantum efficiency, the absorption rate of exciting light of 455 nm, and the internal quantum efficiency can be expressed as follows.

$$External quantum efficiency = Absorption rate of light of 455 nm \times internal quantum efficiency$$

A wavelength of a light-emission peak of the fluorescent substance powder was set as a wavelength at which the highest intensity is exhibited in a wavelength range of 465 nm to 800 nm in the obtained spectrum data obtained by attaching the fluorescent substance powder to the opening of the integrating sphere.

### <Measurement of Chromaticity X Relating to Cured Resin Sheet in Which Fluorescent Substance Powder is Dispersed>

### [Preparation of Cured Resin Sheet (Measurement Sample)]

First, 40 parts by mass of fluorescent substance powder to be measured, and 60 parts by mass of silicone resin (trade name: OE-6630, manufactured by Dow Corning Toray Co., Ltd.) were stirred and defoamed by using rotation and revolution mixer to obtain a uniform mixture (liquid). Next, the mixture was dropped onto a first transparent fluorine resin film, and a second transparent fluorine resin film was superimposed on the dropped object to obtain a sheet-shaped stacked object. In addition, with respect to the sheet-shaped stacked object, a layer thickness of the dropped object was adjusted by using a roller having a gap obtained by adding 50 μm to the total thickness of the first fluorine resin film and the second fluorine resin film, and the sheet-shaped stacked object was shaped into a non-cured sheet.

The non-cured sheet was heated under a condition of 150° C. for 60 minutes. After the heating, the first fluorine resin film and the second fluorine resin film were peeled off to obtain a cured resin sheet which has a film thickness of 50±5 μm and in which fluorescent substances are dispersed.

### [Measurement of Chromaticity X]

A blue light-emitting diode (blue LED) having a peak wavelength within a range of 450 nm to 460 nm was prepared. One main surface of the resin cured sheet was irradiated with blue light emitted from the blue LED, and a light-emission spectrum of light emitted from the other main surface side of the resin cured sheet was measured. From spectrum data in a wavelength region in a range of 400 nm to 800 nm of the light-emission spectrum, a CIE chromaticity coordinate x value (chromaticity X) in an XYZ colorimetric system defined by JIS Z 8781-3:2016 was obtained through calculation conforming to JIS Z 8724:2015 “Methods of colour measurement-Light-source colour”. As the value of X is larger, a red expression region of the red fluorescent substance becomes wider, and this leads to a color gamut of the LED display.

Note that, as the blue light-emitting diode used in the measurement, a light-emitting diode (product number: SMT type, PLCC-6, 0.2 W, SMD 5050 LED) in which a peak wavelength is 450 nm to 460 nm, chromaticity X is 0.145 to 0.165, and chromaticity Y is 0.023 to 0.037 was used.

TABLE 1

| | | | Example | Example | Example | Example | Example |
|---|---|---|---|---|---|---|---|
| | | | 1 | 2 | 3 | 4 | 5 |
| Manufacturing | Raw material | Si₃N₄ | 25.7 | 25.7 | 25.7 | 25.7 | 24.1 |
| conditions | composition | AlN | 22.5 | 22.5 | 22.5 | 22.5 | 21.2 |
| | [% by mass] | Ca₃N₂ | 3.0 | 3.0 | 3.0 | 3.0 | 2.3 |
| | | Sr₂N | 43.1 | 43.1 | 43.1 | 43.1 | 41.5 |
| | | Eu₂O₃ | 5.8 | 5.8 | 5.8 | 5.8 | 10.9 |
| | Firing | Firing temperature [° C.] | 1930 | 1930 | 1930 | 1930 | 1550 |
| | process | Firing time [hour] | 4 | 4 | 4 | 4 | 12 |
| | | Pressure of atmosphere [MPaG] | 0.85 | 0.85 | 0.85 | 0.85 | 0.03 |
| | Annealing | Heating temperature [° C.] | 1350 | 1350 | 1350 | 1350 | 1350 |
| | process | Heating time [hour] | 8 | 8 | 8 | 8 | 4 |
| | | Pressure of atmosphere [MPaG] | 0.03 | 0.03 | 0.03 | 0.03 | 0.03 |
| | Pulverization | Ball diameter [mm] | 5 | 5 | 5 | 5 | 1 |
| | process | Blending amount of aqueous | 3.13 | 3.13 | 3.13 | 3.13 | 4.17 |
| | | solution [% by volume] | | | | | |
| | | Pulverization time [hour] | 15 | 15 | 20 | 15 | 50 |
| | Classification | Particle size setting value of | — | 1.5 | 1.5 | 2.0 | 15 |
| | process | particle to be removed [μm] | | | | | |
| Fluorescent | Circularity | Maximum value | 0.943 | 0.943 | 0.943 | 0.943 | 0.951 |
| substance | | Minimum value | 0.266 | 0.339 | 0.378 | 0.225 | 0.342 |
| powder | | Average value (average circularity) | 0.821 | 0.824 | 0.833 | 0.821 | 0.831 |
| | | standard deviation | 0.059 | 0.058 | 0.042 | 0.072 | 0.051 |

| | | | | | | |
|---|---|---|---|---|---|---|
| | Average aspect ratio | 1.198 | 1.210 | 1.148 | 1.272 | 1.184 |
| | Average equivalent circle diameter [μm] | 2.2 | 2.3 | 1.9 | 2.6 | 1.9 |
| Evaluation | Optical absorption rate [%] | 82.0 | 90.2 | 84.5 | 91.4 | 93.9 |
| | Internal quantum efficiency [%] | 65.4 | 72.3 | 72.6 | 75.7 | 69.2 |
| | External quantum efficiency [%] | 53.6 | 65.3 | 61.3 | 69.2 | 64.9 |
| | Light-emission peak wavelength [nm] | 633 | 633 | 632.1 | 633.9 | 649.5 |
| | Chromaticity X | 0.662 | 0.665 | 0.663 | 0.658 | 0.671 |

| | | | Comparative | Comparative | Comparative |
|---|---|---|---|---|---|
| | | | Example 1 | Example 2 | Example 3 |
| Manufacturing | Raw material | Si₃N₄ | 25.7 | 25.5 | 25.5 |
| conditions | composition | AlN | 22.5 | 22.4 | 22.4 |
| | [% by mass] | Ca₃N₂ | 3.0 | 2.4 | 2.4 |
| | | Sr₂N | 43.1 | 43.9 | 43.9 |
| | | Eu₂O₃ | 5.8 | 5.8 | 5.8 |
| | Firing | Firing temperature [° C.] | 1930 | 1650 | 1950 |
| | process | Firing time [hour] | 4 | 4 | 8 |
| | | Pressure of atmosphere [MPaG] | 0.85 | 0.85 | 0.85 |
| | Annealing | Heating temperature [° C.] | 1350 | 1350 | 1350 |
| | process | Heating time [hour] | 8 | 8 | 8 |
| | | Pressure of atmosphere [MPaG] | 0.03 | 0.03 | 0.03 |
| | Pulverization | Ball diameter [mm] | — | — | — |
| | process | Blending amount of aqueous | — | — | — |
| | | solution [% by volume] | | | |
| | | Pulverization time [hour] | — | — | — |
| | Classification | Particle size setting value of | — | — | — |
| | process | particle to be removed [μm] | | | |
| Fluorescent | Circularity | Maximum value | 0.943 | 0.951 | 0.938 |
| substance | | Minimum value | 0.269 | 0.252 | 0.103 |
| powder | | Average value (average circularity) | 0.807 | 0.773 | 0.704 |
| | | standard deviation | 0.084 | 0.111 | 0.122 |

| | | | | |
|---|---|---|---|---|
| | Average aspect ratio | 1.281 | 1.362 | 1.756 |
| | Average equivalent circle diameter [μm] | 3.8 | 3.2 | 13.1 |
| Evaluation | Optical absorption rate [%] | 94.5 | 93.8 | 97.7 |
| | Internal quantum efficiency [%] | 72.1 | 82.4 | 79.5 |
| | External quantum efficiency [%] | 68.1 | 77.3 | 77.7 |
| | Light-emission peak wavelength [nm] | 636.8 | 641 | 640.5 |
| | Chromaticity X | 0.449 | 0.622 | 0.263 |

### INDUSTRIAL APPLICABILITY

According to the present disclosure, it is possible to provide a fluorescent substance powder containing a red-fluorescent substance capable of exhibiting large chromaticity X of a cured resin layer in a case of being dispersed in a resin to form the cured resin layer. According to the present disclosure, it is possible to provide a light-emitting device that includes the above-described fluorescent substance powder and is capable of exhibiting excellent color reproducibility.

1. A fluorescent substance powder comprising:
a plurality of CASN-based fluorescent substance particles,
wherein average circularity of fluorescent substance particles having a particle size of 1 μm or greater among the CASN-based fluorescent substance particles is 0.820 or greater, and a standard deviation of the circularity is less than 0.080.

2. The fluorescent substance powder according to claim 1,
wherein an average aspect ratio of fluorescent substance particles having a particle size of 1 μm or greater among the CASN-based fluorescent substance particles is 1.275 or less.

3. The fluorescent substance powder according to claim 1,
wherein a main crystal phase constituting the CASN-based fluorescent substance has the same structure as in a CaAlSiN₃ crystal phase.

4. The fluorescent substance powder according to claim 1,
wherein the fluorescent substance powder is expressed by a general formula of (CaₓSr_{y}Eu_{z}) AlSiN₃, and in the general formula, conditions of 0≤x<1, 0<y<1, and 0<z<1 are satisfied.

5. The fluorescent substance powder according to claim 1,
wherein a wavelength of a light-emission peak is 605 nm to 670 nm.

6. A light-emitting device, comprising:
a light-emitting element that emits primary light; and
a wavelength converter that absorbs a part of the primary light and emits secondary light having a wavelength longer than a wavelength of the primary light,
wherein the wavelength converter comprises the fluorescent substance powder according to claim 1.
